(19) United States
(12) Patent Application Publication
(10) Pub. No.: US 2006/0240660 A1
(43) Pub. Date: Oct. 26, 2006

(54) SEMICONDUCTOR STUCTURE AND METHOD OF MANUFACTURING THE SAME

(76) Inventor: Jin-Sheng Yang, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/907,890

(22) Filed: Apr. 20, 2005

(51) Int. Cl. H01L 21/4763

(52) U.S. Cl. 438/622

(57) ABSTRACT

A semiconductor structure for a substrate having electronic elements formed thereon. The semiconductor structure comprises a dielectric layer and a conductive stuffing material. The dielectric layer is located over the substrate. It should be noticed that the dielectric layer has a plurality of trenched and a border shape of each trench is a non-straight shape. The conductive stuffing material fills the trenches to form an interconnect structure.

### BACKGROUND OF THE INVENTION

1. Field of Invention

The present invention relates to a semiconductor structure and a method of manufacturing the semiconductor structure. More particularly, the present invention relates to an interconnect structure and a method of manufacturing the interconnect structure.

2. Description of Related Art

In the process of manufacturing an integrated circuit, interconnects are used to connect electronic elements to each other. As the increase of the integration of the integrated circuit, in order to accommodate to the increased requirement of interconnects due to decreasing the size of the electronic elements, it is common to use more than two conductive layers to construct the interconnects for connecting electronic elements to each other. In order to prevent the conductive layers from forming a short circuit by directly connecting to each other, the conductive layers are isolated from each other by using an inter-metal dielectric between the conductive layers. Further, the plugs are used to connect the successive conductive layers.

Conventionally, the borders of the interconnects for connecting the electronic elements in touch with the inter-metal dielectric are straight. However, this kind of layout would leads to hardly releasing the stress of the interconnects and poor adhesion between the interconnects and the inter-metal dielectrics.

### SUMMARY OF THE INVENTION

Accordingly, at least one objective of the present invention is to provide a semiconductor structure having a non-straight-border-shape interconnect structure. Because of the non-straight-border-shape interconnect structure, the stress of the interconnect structure can be well distributed through the irregular borders. Hence, the delamination phenomenon can be alleviated and the defects due to delamination can be reduced. Further, since the border of the interconnect structure is irregular, the adhesion between two different type material, such as the conductive material and the dielectric material, can be increased and the reliability of the semiconductor structure is increased as well.

At least another objective of the present invention is to provide a method of manufacturing a semiconductor structure capable of well distributing the stress of the conductive material to the non-straight border of the interconnect structure. Besides, because of the non-straight border of the interconnect structure, the adhesion between the conductive material and the dielectric material is increased and the reliability of the semiconductor structure is also increased.

To achieve these and other advantages and in accordance with the purpose of the invention, as embodied and broadly described herein, the invention provides a semiconductor structure for a substrate having electronic elements formed thereon. The semiconductor structure comprises a dielectric layer and a conductive stuffing material. The dielectric layer is located over the substrate. It should be noticed that the dielectric layer has a plurality of trenched and a border shape of each trench is a non-straight shape. The conductive stuffing material fills the trenches to form an interconnect structure.

In the present invention, the conductive stuffing material can be metal copper. Besides, the non-straight shape can be a zigzag shape, a wavy shape or an irregular shape comprising a plurality of protruding-recession pairs.

The present invention also provides a semiconductor structure for a substrate having electronic elements formed thereon. The semiconductor structure comprises a dielectric layer and an interconnect structure. The dielectric layer is located over the substrate. The interconnect structure is located in the dielectric layer and the interconnect structure is composed of a plurality of wire sections and a border shape of each wire section is a non-straight shape.

In the present invention, the interconnect structure is formed from metal copper. Further, the non-straight shape can be a zigzag shape, a wavy shape or an irregular shape comprising a plurality of protruding-recession pairs.

The present invention further provides a method of manufacturing a semiconductor structure for a substrate having electronic elements formed thereon. The method comprises steps of forming a dielectric layer over the substrate and forming a trench in the dielectric layer. It should be noticed that a border shape of the trench is a non-straight shape. Finally, the trench is filled with a conductive material to form an interconnect structure.

In the present invention, the step of forming the trench further comprises steps of forming a photoresist layer with a thickness on the dielectric layer, patterning the photoresist layer by using a photomask having a designed pattern, patterning the dielectric layer by using the patterned photoresist layer as a mask and removing the patterned photoreisist layer. More specifically, the thickness of the photoresist layer is less than that of the dielectric layer. Alternatively, a border shape of the designed pattern on the photomask is a non-straight shape. Further, the conductive material can be metal copper.

Since the border of the interconnect structure is non-straight, the stress of the interconnect structure can be well distributed through the irregular borders. Therefore, the delamination phenomenon can be alleviated and the defects due to delamination can be reduced. Further, because the border of the interconnect structure is irregular, the adhesion between the conductive material and the dielectric material can be increased and the reliability of the semiconductor structure is increased as well.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A through FIG. 1C are three-dimensional views showing a method of manufacturing a semiconductor structure according to one of the preferred embodiments of the invention.

FIG. 2 is a top view of FIG. 1C showing an interconnect structure having a non-straight border.

FIG. 3A through FIG. 3C are three-dimensional views showing a method of manufacturing a semiconductor structure according to one of the preferred embodiments of the invention.

FIG. 4 is a top view of FIG. 1C showing an interconnect structure having a non-straight border.

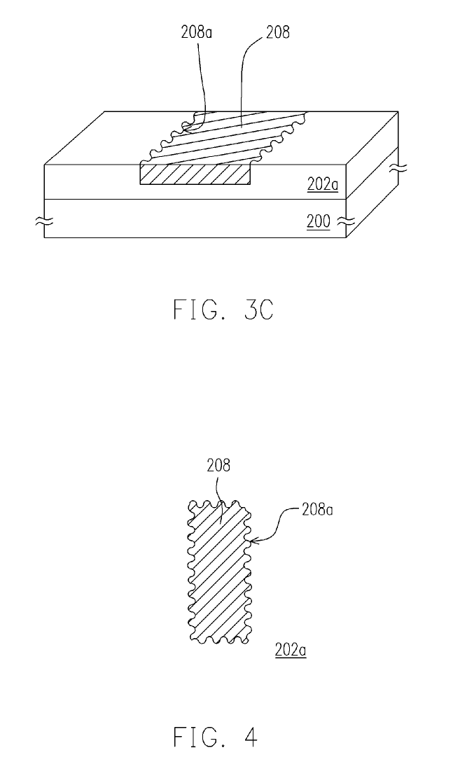

### DESCRIPTION OF THE PREFERRED EMBODIMENTS

In the invention, a novel semiconductor structure and a novel approach for manufacturing the semiconductor structure are proposed. The semiconductor structure according to the invention possesses an interconnect structure having non-straight border. Because of the non-straight border, the stress of the interconnects can be well distributed and the adhesion between the interconnects and the inter-metal dielectric can be improved.

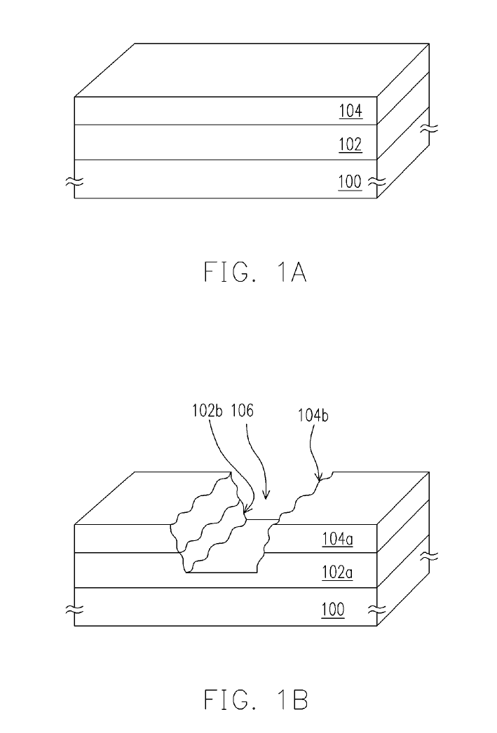

FIG. 1A through FIG. 1C are three-dimensional views showing a method of manufacturing a semiconductor structure according to one of the preferred embodiments of the invention. As shown in FIG. 1A, a substrate 100 is provided, wherein the substrate 100 has at least one electronic element formed therein. Thereafter, a dielectric layer 102 is formed over the substrate 100. The dielectric layer 102 can be, for example, formed from silicon oxide, borophosphosilicate glass (BPSG), phosphosilicate glass (PSG), silicon nitride or silicon oxy-nitride by atmospheric chemical vapor deposition (APCVD), low pressure chemical vapor deposition (LPCVD) or plasma-enhanced chemical vapor deposition (PECVD). Then, a photoresist layer 104 is formed on the dielectric layer 102. Notably, the thickness of the photoresist layer 104 is less than that of the dielectric layer 102. More specifically, the thickness of the photoresis layer 104 is much less than the requirement of the design rule.

As shown in FIG. 1B, a photolithography process is performed to pattern the photoresist layer 104 and the photoresist layer 104 is transformed into a photoresist layer 104a having a trench pattern (not shown). Thereafter, an etching process is performed to pattern the dielectric layer 102 by using the photoresist layer 104a as a mask so that the dielectric layer 102 is transformed into a dielectric layer 102a having a trench 106. Since the thickness of the photoresist layer 104a is much less than the required thickness for being as an etching mask in the etching process, the sidewall of the photoresist layer 104a is consumed by the etchant and becomes slant during the etching process. Therefore, the edge of the photoresist layer 104a is no longer straight but becomes non-straight. As a result, by using the photoresist layer 104a with a non-straight border 104b as an etching mask, the trench 106 formed in the dielectric layer 102a also possesses a non-straight border 102b.

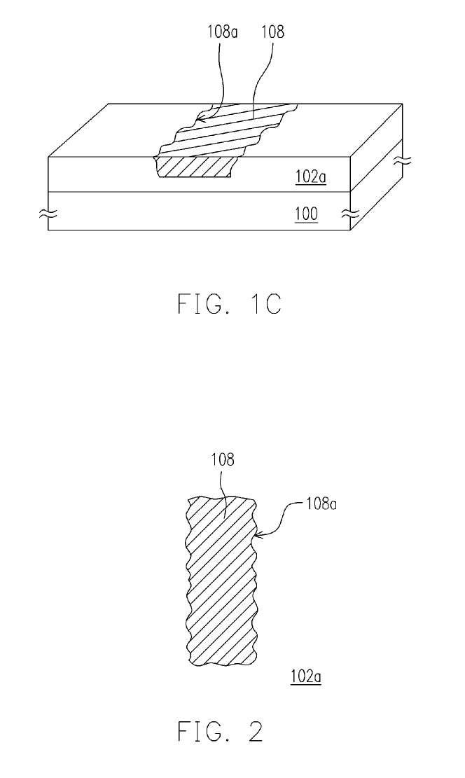

As shown in FIG. 1C together with FIG. 2, the top view of FIG. 1C, the photoresist layer 104a is removed. Then, the trench 106 (shown in FIG. 1B) is filled with a conductive material to form an interconnect structure 108. The interconnect structure 108 can be, for example, formed from metal copper. Because the border of the trench 102b is non-straight, the interconnect structure 108 formed in the trench 106 also possesses a non-straight border 108a.

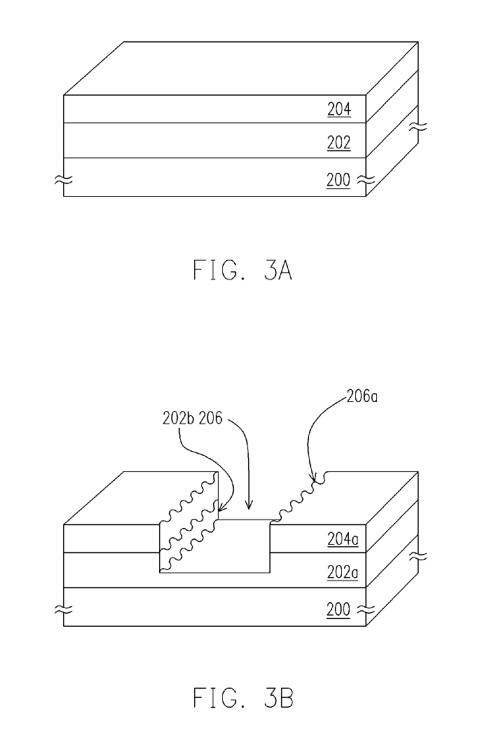

FIG. 3A through FIG. 3C are three-dimensional views showing another method of manufacturing a semiconductor structure according to one of the preferred embodiments of the invention. As shown in FIG. 3A, a substrate 200 is provided, wherein the substrate 200 has at least one electronic element formed therein. Thereafter, a dielectric layer 202 is formed over the substrate 200. The dielectric layer 202 can be, for example, formed from silicon oxide, borophosphosilicate glass (BPSG), phosphosilicate glass (PSG), silicon nitride or silicon oxy-nitride by atmospheric chemical vapor deposition (APCVD), low pressure chemical vapor deposition (LPCVD) or plasma-enhanced chemical vapor deposition (PECVD). Then, a photoresist layer 204 is formed on the dielectric layer 202.

As shown in FIG. 3B, a photolithography process is performed to pattern the photoresist layer 204 by using a photomask (not shown) and the photoresist layer 204 is transformed into a photoresist layer 204a having a trench pattern (not shown). Notably, the photomask has a designed pattern, and the border shape of the designed pattern on the photomask is a non-straight shape. The non-straight shape can be, for example, a zigzag shape, a wavy shape or an irregular shape comprising a plurality of protruding-recession pairs. After the photolithography process, the designed pattern on the photomask is transferred onto the photoresist layer 204 and the border of the trench pattern in the photoresist layer 204a is also non-straight. Thereafter, an etching process is performed to pattern the dielectric layer 202 by using the photoresist layer 204a as a mask so that the dielectric layer 202 is transformed into a dielectric layer 202a having a trench 206. Since the sidewall of the photoresist layer 204a is non-straight, the border 202b of the trench 206 formed in the dielectric layer 202a is also non-straight. The edge of the trench 206 formed in the dielectric layer 202a can be, for example, a zigzag shape, a wavy shape or an irregular shape comprising a plurality of protruding-recession pairs.

As shown in FIG. 3C together with FIG. 3, the top view of FIG. 1C, the photoresist layer 204a is removed. Then, the trench 206 (shown in FIG. 3B) is filled with a conductive material to form an interconnect structure 208. The interconnect structure 208 can be, for example, formed from metal copper. Because the border of the trench 202b is non-straight, the interconnect structure 208 formed in the trench 206 also possesses a non-straight border 208a.

In the both preferred embodiment of the present invention, a single interconnect/conductive wire formed in a single trench is used to represent the interconnect structure in the dielectric layer. However, in the application of the present invention, the interconnect structure is composed of several wire sections formed in trenches in the dielectric layer and the border shape of each wire section is non-straight shape.

In the present invention, because of the non-straight-border-shape interconnect structure, the stress of the interconnect structure can be well distributed through the irregular borders. Hence, the delamination phenomenon can be alleviated and the defects due to delamination can be reduced. Further, since the border of the interconnect structure is irregular, the adhesion between two different type material, such as the conductive material and the dielectric material, can be increased and the reliability of the semiconductor structure is increased as well.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A semiconductor structure for a substrate having electronic elements formed thereon, the semiconductor structure comprising:
a dielectric layer located over the substrate, wherein the dielectric layer has a plurality of trenched and a border shape of each trench is a non-straight shape; and
a conductive material filling the trenches to form an interconnect structure.

2. The semiconductor structure of claim 1, wherein the conductive material can be metal copper.

3. The semiconductor structure of claim 1, wherein the non-straight shape can be a zigzag shape.

4. The semiconductor structure of claim 1, wherein the non-straight shape can be a wavy shape.

5. The semiconductor structure of claim 1, wherein the non-straight shape can be an irregular shape comprising a plurality of protruding-recession pairs.

6. A semiconductor structure for a substrate having electronic elements formed thereon, the semiconductor structure comprising:
a dielectric layer located over the substrate; and
an interconnect structure located in the dielectric layer, wherein the interconnect structure is composed of a plurality of wire sections and a border shape of each wire section is a non-straight shape.

7. The semiconductor structure of claim 6, wherein the interconnect structure is formed from metal copper.

8. The semiconductor structure of claim 6, wherein the non-straight shape can be a zigzag shape.

9. The semiconductor structure of claim 1, wherein the non-straight shape can be a wavy shape.

10. The semiconductor structure of claim 1, wherein the non-straight shape can be an irregular shape comprising a plurality of protruding-recession pairs.

11. A method of manufacturing a semiconductor structure for a substrate having electronic elements formed thereon, the method comprising:
forming a dielectric layer over the substrate;
forming a trench in the dielectric layer, wherein a border shape of the trench is a non-straight shape; and
filling the trench with a conductive material to form an interconnect structure.

12. The method of claim 11, wherein the step of forming the trench further comprises steps of:
forming a photoresist layer with a thickness on the dielectric layer;
patterning the photoresist layer by using a photomask having a designed pattern;
patterning the dielectric layer by using the patterned photoresist layer as a mask; and
removing the patterned photoreisist layer.

13. The method of claim 12, wherein the thickness of the photoresist layer is less than that of the dielectric layer.

14. The method of claim 12, wherein a border shape of the designed pattern on the photomask is a non-straight shape.

15. The method of claim 11, wherein the conductive material can be metal copper.
